(19) United States
(12) Patent Application Publication
(10) Pub. No.: US 2015/0116958 A1
(43) Pub. Date: Apr. 30, 2015

(54) CIRCUIT BOARD MODULES HAVING MECHANICAL FEATURES

(71) Applicant: Apple Inc., Cupertino, CA (US)

(72) Inventors: Anna-Katrina Shedletsky, Mountain View, CA (US); Samuel Bruce Weiss, Menlo Park, CA (US)

(21) Appl. No.: 14/446,458

(22) Filed: Jul. 30, 2014

Related U.S. Application Data
(60) Provisional application No. 61/896,323, filed on Oct. 28, 2013.

(51) Int. Cl. H05K 1/18; H05K 9/00

(52) U.S. Cl. CPC H05K 1/185; H05K 9/0024
USPC 361/748

(57) ABSTRACT

A modularized printed circuit board including mechanical features. The modularized printed circuit board may include a printed circuit board, at least one electronic component affixed to the printed circuit board, and an overmold material adjacent at least a portion of the printed circuit board and defining a region of overmold material. The modularized printed circuit board may also include a feature formed from the overmold material.

### CROSS-REFERENCE TO RELATED APPLICATION

This application is a nonprovisional patent application of and claims the benefit to U.S. Provisional Patent Application No. 61/896,323, filed Oct. 28, 2013 and titled “Circuit Board Modules Having Mechanical Features,” the disclosure of which is hereby incorporated herein by reference in its entirety.

### TECHNICAL FIELD

Embodiments described herein relate generally to circuit board modules, and more particularly to circuit board modules having mechanical and/or optical features formed in an overmolded material.

### BACKGROUND

Modularizing a collection of components into a self-contained board that can be then pick-and-placed onto a main circuit board as part of a manufacturing operation is often used for certain printed circuit board (PCB) modules, such as certain radio components. This may allow, for example, fast and precise assembly of PCB modules that have a preconfigured layout and known electromagnetic profile during operation, as well as the optional addition of electromagnetic shielding. Thus, assembly of an electronic device may be quickly and efficiently performed.

Generally, the self-contained PCB may include multiple electronic components, such as integrated circuit chips, capacitors, resistive elements, digital logic, antennas and the like. However, such self-contained PCBs often need to be fastened or otherwise affixed to the main circuit board. Separate mechanical fasteners may be used to affix the two, but this often requires offsetting space on at least the self-contained PCB that cannot be used for the placement of electronic circuitry. Further, the mechanical fasteners may occupy significant space within an electronic device, thereby reducing the amount of available space for electronics that provide or support features and functionality.

### SUMMARY

Generally, embodiments described herein may take the form of a modularized printed circuit board, including a printed circuit board, at least one electronic component affixed to the printed circuit board, an overmold material adjacent at least a portion of the printed circuit board and defining a region of overmold material, and a feature formed from the overmold material.

Certain embodiments may have a feature that extends laterally away from the printed circuit board and does not overlie the printed circuit board. In some embodiments, the feature comprises a securing structure operative to secure the modularized printed circuit board to a support.

In still other embodiments, the securing structure is affixed to the support. Further, in some embodiments the securing structure is affixed directly to the support without the use of a fastener.

Still other embodiments may include a second region of overmold material adjacent the first region of overmold material, wherein the first and second overmold materials are formed from different materials. In some such embodiments, the second overmold material is optically transparent. Further, in some embodiments the second region of overmold material overlies an electronic component operative to receive light through the second region of overmold material.

These and other embodiments and advantages will be apparent to those of ordinary skill in the art upon reading this document in its entirety.

### BRIEF DESCRIPTION OF THE FIGURES

The disclosure will be readily understood by the following detailed description in conjunction with the accompanying drawings, wherein like reference numerals designate like structural elements, and in which:

FIG. 1 depicts an isometric view of a sample modularized printed circuit board having a first feature overmolded therein.

FIG. 2 depicts a cross-sectional view of the sample modularized printed circuit board of FIG. 1, depicting a first overmolded feature.

FIG. 3 depicts a cross-sectional view of a second sample modularized printed circuit board having a second feature overmolded therein.

FIG. 4 depicts a cross-sectional view of a third sample modularized printed circuit board having a third feature joined to the circuit board by an overmolded material.

FIG. 5 depicts a cross-sectional view of a fourth sample modularized printed circuit board having a fourth feature overmolded therein.

FIG. 6A depicts a first sample connection feature formed within a region of overmold material of a modularized circuit board.

FIG. 6B depicts a second sample connection feature at least partially encased in a region of overmold material of a modularized circuit board.

FIG. 6C depicts a third sample connection feature affixed to a region of overmold material of a modularized circuit board.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION

Generally, embodiments described herein may take the form of a printed circuit board (PCB) having one or more features overmolded thereon. For example, a PCB may have a number of electronic components placed, positioned, or affixed thereto. An electrically inert or insulating material, such as certain polymers, resins and the like, may be overmolded onto the PCB and may cover the electronic components thereon. This combination of overmolded material and PCB may be referred to herein as a “modularized circuit board” or “modularized PCB.”

The overmolded material may be electrically inert, or insulating, in order to avoid interference with the electronic components on the PCB. The overmolded material may, however, provide a barrier against external moisture, dust, dirt, debris and the like, and may hermetically seal the electronic components against the environment. Thus, the electronic components may operate normally while the overmolded material physically shields the components.

In some embodiments, the overmolded material may also conduct heat away from the electronic components and to a surface of the material. In still other embodiments, thermal paths may be defined within the overmolded material. As one example, a material that is particularly thermally conductive may be initially placed with respect to the PCB and/or components, and then the overmolded material may be applied to the thermally conductive material and the electronic components. This may be done, as one example, as a two-shot molding process. As another example, the thermally conductive paths may be adhered or otherwise affixed to the PCB and/or components and then the overmolded material injected or otherwise applied to the resulting structure.

As another option, certain mechanical features may be formed in the overmolded material. For example, a snap, detent, groove, ramp, cutaway or other mating or affixing structure may be formed in the overmolded material. This mating or affixing structure may be used to secure the modularized PCB to another circuit board (such as a motherboard), an enclosure, an internal support, or the like. Further, the mating structure may cooperate with a fastener, such as a screw or bolt, to affix the modularized PCB in such a fashion.

It should be appreciated that the mating or affixing structure (referred to herein for simplicity as a “mating structure”) may be formed in the overmold material only, or may be formed in the overmold material and the PCB. As one non-limiting example of the former, a portion of the overmold material may extend laterally outwardly from the PCB. This lateral extension may have the mating structure formed therein so that any fastener extends only through the overmold material and not through the PCB. In some embodiments, the overmold material forming the lateral extension may be the same thickness as the overmold material over the PCB, thereby permitting a boss or other support to underlie the overmold material at a height that is contiguous with (or less than) the thickness of the PCB. In other embodiments, the overmold material may extend along a vertical edge of the PCB (e.g., along the thickness of the PCB) in the lateral extension. Thickening the overmold material in this manner may strengthen the lateral extension and thus the mating structure.

In certain embodiments, one or more optical features may be formed within the overmold material, or from a separate material that is embedded in the overmold material. For example, an optically clear resin may be used to form the overmold material. As another option, an optically clear material may be co-molded with an optically opaque overmold material, such that the optically clear material forms a feature above only a portion of the encapsulated PCB and/or electronic components.

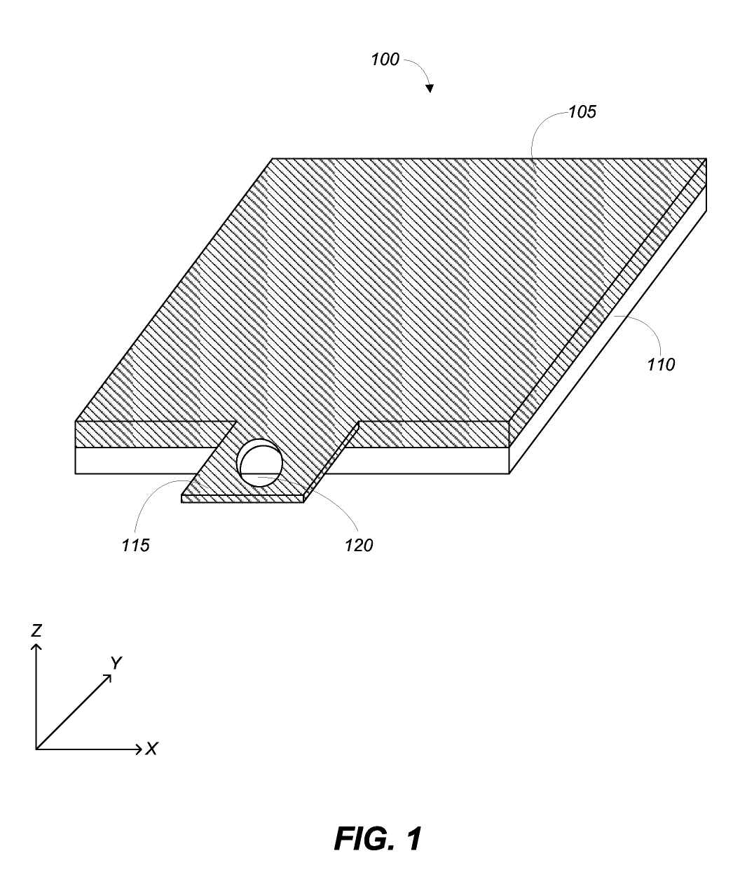

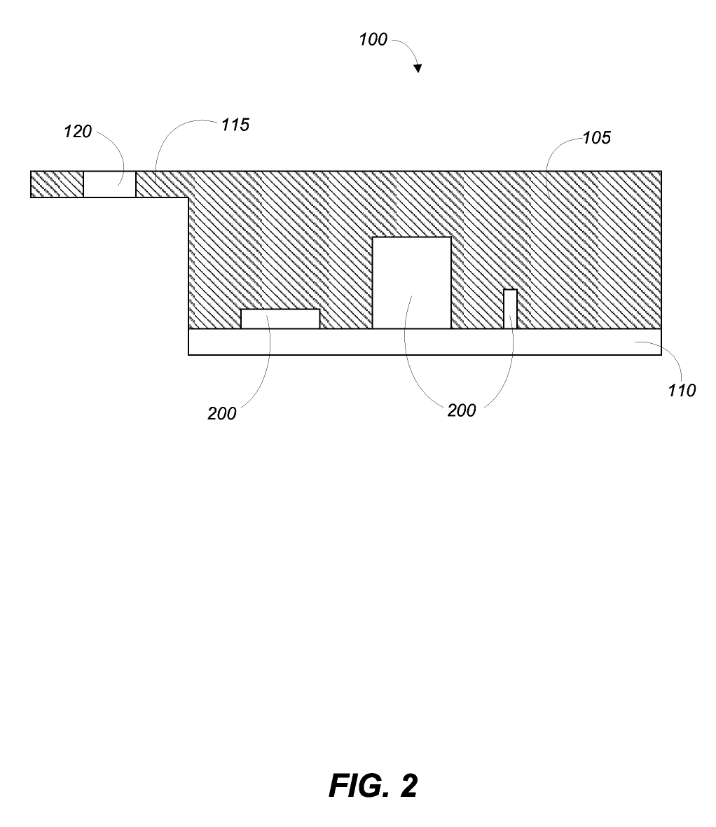

Various embodiments and features will now be described. FIG. 1 depicts an isometric view of a sample modularized printed circuit board 100 having a first feature overmolded therein. As shown in FIG. 1, an overmold material 105 may overlie a PCB 110 and at least partially encapsulate one or more electronic components 200 (shown in FIG. 2) affixed to the PCB. Although the embodiment of FIG. 1 shows the overmold material as coplanar with the PCB, it should be appreciated that, in alternative embodiments, the overmold material may extend downwardly along one or more sidewalls of the PCB.

As mentioned above, the overmold material 105 is generally an electrical insulator in order to avoid interference with the operation of the PCB 110 and associated electronic components 200. The overmold material may be radio-frequency transparent, or transparent to another portion of the electromagnetic spectrum, in order to permit certain electronic components 200 to operate (for example, transceivers and the like). The overmold material may be bonded directly to the PCB and/or the electronic components 200 or an air gap between the overmold material and one or more electronic components 200 and/or portions of the PCB may be present.

In some embodiments, the overmold material 105 may be a glass fiber composite. That is, the resin or polymer (or the like) of the overmold material may have multiple glass fibers suspended therein. The glass fibers may be randomly aligned or may be aligned in a specific pattern, such as parallel to one another. Generally, the glass fibers may impart strength and resistance to bending or breaking to the overmold material. In alternative embodiments, other fibers may be used in place of the glass fibers, such as carbon fibers and the like. Likewise, some embodiments may omit such fibers entirely.

As also shown in FIG. 1, a feature 115 is formed from the overmold material 105 and contiguously with the portion of the overmold material overlying the PCB 110. In the example of FIG. 1, the feature is a securing structure having the form of a tab or extension with a through hole 120 defined therein.

The extension 115, as shown to better effect in the cross-sectional view of FIG. 2, has a height (e.g., extends in the Z-direction, with respect to the axes shown in FIG. 1) that is less than the overall height over the overmolded PCB 110 and/or the overmolded material 105. It should be appreciated that this difference in height is not necessary but may be useful to provide clearance beneath the extension for a boss, support or other element.

Continuing the example, a screw or other fastener may extend through the hole 120 formed in the extension 115 in order to secure the modularized PCB to a support. The hole 120 may be threaded in some embodiments; the hole 120 and/or threads may be formed at the same time the extension 120 and overmold material 105 is formed, or the hole 120 and/or threads may be machined through the extension 115 as a subsequent operation.

FIG. 2 is a cross-sectional side view showing the extension 115 and through hole 120 in more detail, and depicting the height difference between the extension 115 and overmold material 105 overlying the PCB 110. As shown, the overmold material 105 covers and contacts both the PCB 110 and the electronic components 200 affixed to the PCB 110. Thus, the overmold material may provide an environmental seal for the PCB's 110 upper surface and/or the electronic components 200. In some embodiments, the overmold material 105 may form a hermetic seal.

Further and as also shown in FIG. 2, the extension 115 may be contiguous with the region of overmold material 105. Insofar as the extension 115 is formed from the overmold material 105 and the two are unitary, the extension 115 is less likely to crack or break away from the rest of the modularized PCB 110. Essentially, the unitary nature of the overmold material 105, in both the extension 115 and the region of overmold material 105, imparts greater strength to the extension 115 and thus increases the utility of the extension 115 as a mechanical fastener to hold the modularized PCB in place.

Although FIGS. 1 and 2 show a feature 115 taking the form of an extension with a hole 120 therethrough, it should be appreciated that other features may be formed from the overmold material. Likewise, the features may be formed in different places and/or for different purposes.

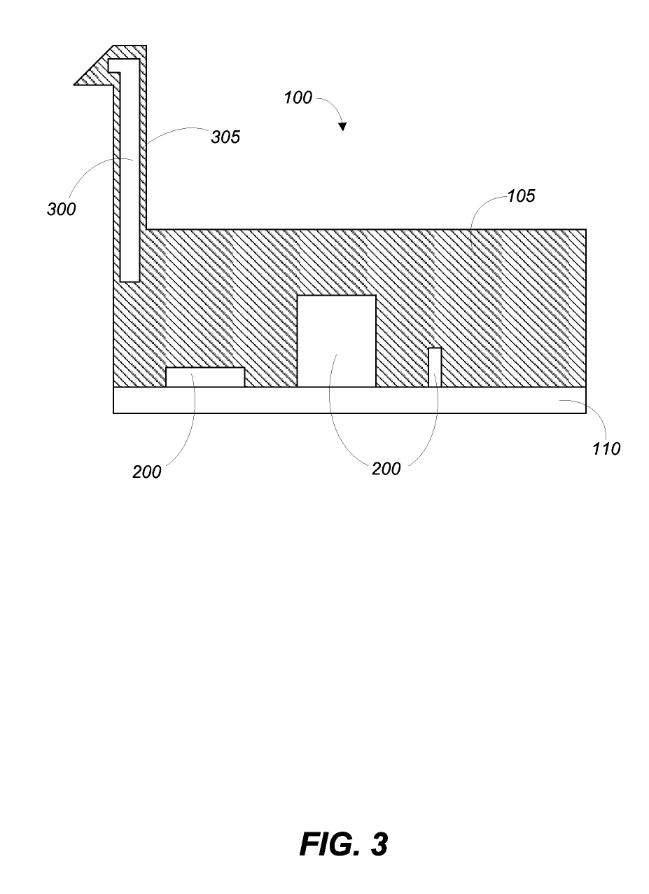

As another example, FIG. 3 depicts another feature 305 that may be co-molded with the region of overmold material 105 of the modularized PCB 100. Here, the feature is a securing structure having the form of a mounting hook 305. The mounting hook may allow the modularized PCB to be affixed to and/or suspended from a support structure, for example. As with the extension of FIG. 2, the mounting hook 305 may be formed simultaneously with the region of overmold material 105 of the modularized PCB or may be formed later. Further, the mounting hook 305 (or any other formed feature) may directly couple to the support structure without the need for any fastener or other structure. For example, the edge of the mounting hook may be received directly within a recess in the support structure and snap-fit, friction-fit or pressure-fit thereto.

Further, it should be appreciated that the various features described herein and present in other embodiments need not be formed from the overmold material 105. That is, the features and overmold materials 105 may be formed separately in a two-shot or multi-shot process. In a multi-shot process, the material used to form the feature(s) may be different from the overmold material 105. For example, a different resin, plastic, polymer and the like may be used. In some embodiments, the material used to form the feature may not be an electrical insulator, insofar as the feature may not contact any electrical component.

Some embodiments may form or create the feature around an internal stiffener, reinforcement, or other structural element. The internal stiffener may be partially or completely encapsulated by the overmold material forming the feature. One example of an internal stiffener 300 is shown in FIG. 3. The internal stiffener 300 may be made of any substantially rigid material, such as metal, a stiff plastic, and the like. The shape of the internal stiffener 300 need not correspond exactly to the feature 305 (e.g., hook) shape. The internal stiffener may extend from the feature into the region of overmold material 105 in order to increase the structural rigidity of the feature 305 and to mechanically couple the feature 305 with other portions of the overmold material 105.

In some embodiments, at least a portion of the internal stiffener 300 may be exposed externally through the surface of the feature and/or region of overmold material 105. Accordingly, the internal stiffener 300 need not be totally encompassed within the feature 305 (e.g., hook) and/or overmold. Likewise, certain connecting structures may be only partially encapsulated in order to secure the connecting structure, and thus the modularized PCB, to a support. The location and configuration of any such connecting structure may vary between embodiments.

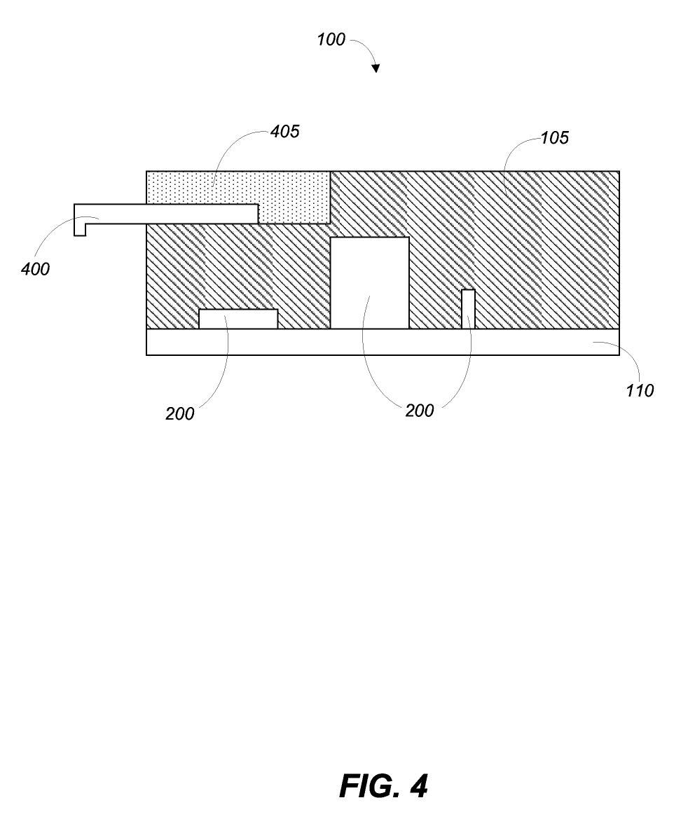

As one example, FIG. 4 shows a cross-sectional view of a modularized PCB 100 having a mounting structure, such as a connecting structure 400 extending partially outward therefrom. As shown in the figure, the connecting structure 400 may be partially received within the overmold material 410. For example, the connecting structure 400 may be partially encased or encapsulated within the overmold material 405 and may be partially free from encapsulation. In such an embodiment, a first portion of the region of overmold material 105 may be created in a first molding process. After the first portion of the region of overmold material 105 cures, the connecting structure may be placed.

A second shot of material 405, which may be the same or different material as used to create the first portion of the region of overmold material 105, may then be injected into a mold. This second shot of material 405 may bond to the first portion of the region of overmold material 105 and partially surround the connecting structure 400 in order to hold the connecting structure 400 in place. Optionally, the second shot of material may also bond to the connecting structure. The second shot of material may then cure, creating the modularized PCB 100 shown in FIG. 4.

Generally, the first and second shots of material 105, 405 may be the same or different. Further, even if different, the first and second shots may appear visually similar or identical, such that the region of overmold material 105 presents a relatively uniform appearance.

Some embodiments may employ a two-shot process to impart certain mechanical or electrical properties to the modularized PCB. A second shot of more rigid material may envelop or overlie at least a segment of the region of overmold material 105, thereby imparting to that segment increased strength and/or rigidity.

Likewise, a second material may be placed only in or along certain portions of the modularized PCB in order to create localized mechanical or electrical properties. The second shot material may be injected into grooves or channels formed in the region of overmold material 105 from the first shot material, for example, in order to provide structural stiffness. Alternately, the second shot material may be selectively located or placed to provide a conductive path in certain areas, but not in others. This may be useful for routing data signals and/or creating a ground plane on an exterior of the modularized PCB, or as shielding for the electronic components 200 against electrical interference. In the latter example, it may be understood that such shielding need not extend across an entirety of the modularized PCB and so may be localized in any fashion described herein.

As yet another example, a second shot of material may be selectively deposited to provide a shock mounting or friction fit for the modularized PCB. The second shot material may be softer than the region of overmold material 105, and so may absorb kinetic energy due to impact and thus shield the modularized components from damage in the event of a fall. Alternatively, the second shot material may have a rougher finished surface than the overmold material, and so may be selectively deposited to frictionally engage adjacent surfaces and thereby hold the modularized PCB in place. That is, the second shot material may have a higher coefficient of friction when cured than the overmold material.

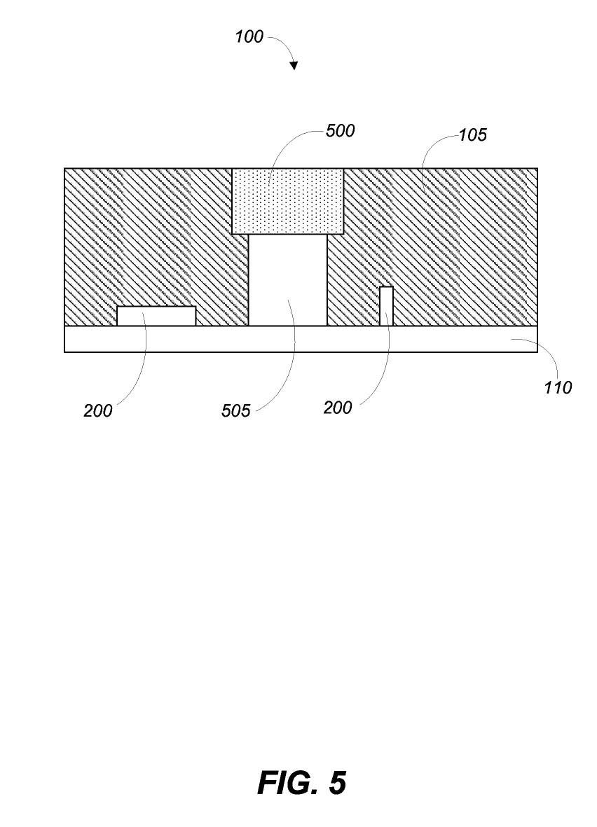

FIG. 5 depicts still another embodiment of a modularized PCB 100. This embodiment may include an optically transparent section 500 that is co-molded or two-shot molded with the region of overmold material 105. A two-shot molding process may be employed to first deposit the overmold material in the region of overmold material 105 and subsequently deposit the optically clear or transparent material to form the transparent section 500. In this fashion, a lens or aperture may be created over an optical element, such as a camera 505, and the camera may capture images through the optically clear region 500.

It should be appreciated that the electronic component 505 located beneath the optically transparent section 500 need not be a camera. It could be an ambient light sensor, a flash, a photodiode, and the like. Further, the optically clear region 500 may be replaced by an infrared-transparent region in some embodiments. An infrared-transparent region may permit an infrared transceiver to function through the overmold of the modularized PCB.

A sample process for creating a modularized PCB 100 having an optically-transparent region 500 will now be discussed. Initially, the overmold material (which may be an electrical insulator) may be deposited in or over regions of the PCB 110 and/or electronic components 200, leaving a void where the optically-transparent region is to be formed. Next, the optically-transparent material may be deposited in the void.

An optional mask may be applied over the surface of the optically-transparent region 500 formed by the optically-transparent material. Following the application of the mask, a conductive shield layer may be optionally sprayed, deposited or otherwise applied to the surface of the region of overmold material 105. Finally, the mask may be removed.

In some embodiments that employ both an optically-transparent region 500 and a conductive shield layer, the conductive shielding material also may be optically transparent (such as indium-tin-oxide), in which case the mask application and removal may be omitted.

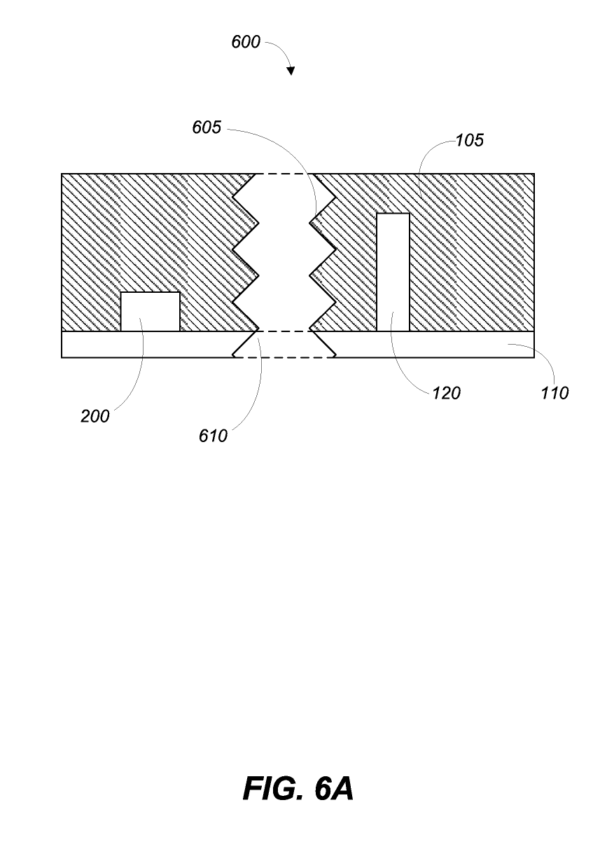

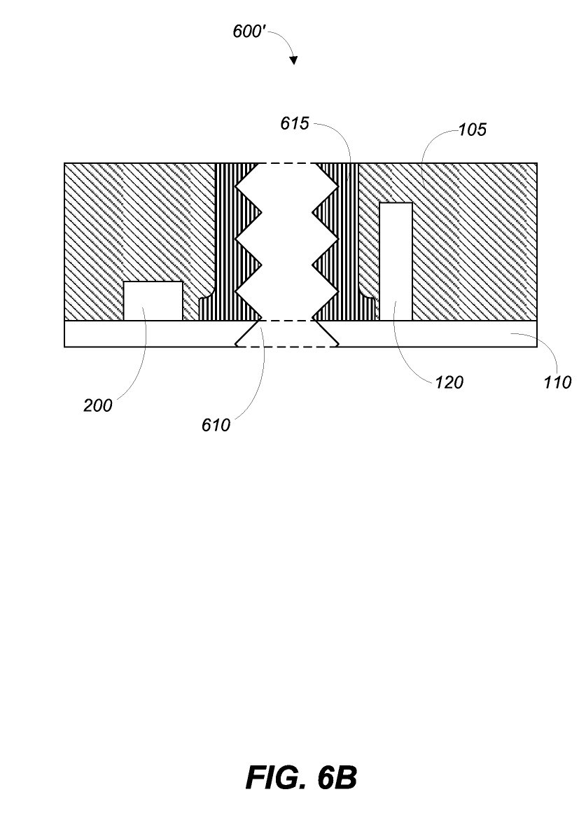

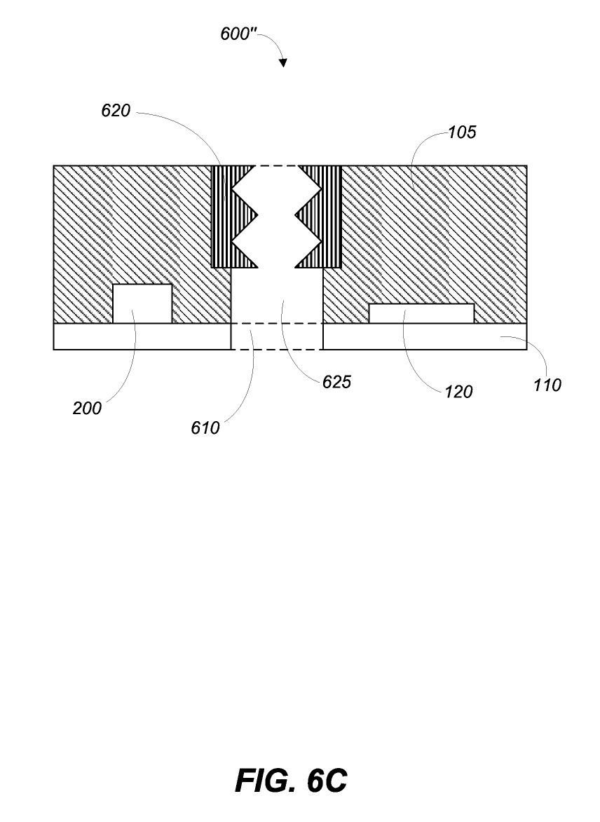

FIG. 6A depicts a first sample connection feature formed within a region of overmold material 105 of a modularized circuit board. In the embodiment 600 shown in FIG. 6A, the region of overmold material 105 is shaped to form a threaded aperture 605 through which a connector can pass to secure the modularized PCB 600 to a substrate. The PCB 110 may have a matching hole 610 extending therethrough and aligned with the threaded aperture 605 in the region of overmold material 105, such that the connector may pass through both the region of overmold material 105 and PCB 110 to affix the modularized PCB to a substrate. In some cases, the connector may include a threaded fastener.

It should be appreciated that the rear portion of the overmold material forming the aperture wall is not shown in the region of the aperture 605 for purposes of clarity only, although it would be visible in the contemplated cross-section. The same is true for the rear portion of the PCB aperture. Dashed lines are used to indicate these regions.

It should be appreciated that the aperture 605 formed in the region of overmold material 105 or material need not be threaded, but instead could be smooth or have other mating features. For example, detents, grooves, saw teeth and the like could be formed in or along the sidewall(s) of the aperture 605 in lieu of, or in addition to, threading.

FIG. 6B depicts a second sample connection feature at least partially encased in a region of overmold material 105 of a modularized circuit board. In this embodiment 600′, a threaded nut 615 may be affixed to, or placed on, the PCB 110 prior to depositing the overmold material 105. The overmold material 105 may lock the nut 615 in place with respect to the PCB and any aperture 610 formed in the PCB 110. Generally, the interior of the nut 615 remains free of overmold material and may be shielded when the overmold material is applied to the PCB 110; such shielding may be removed after overmold deposition.

FIG. 6C depicts a third sample connection feature affixed to a region of overmold material 105 of a modularized circuit board. Here, a threaded connector 620 may be adhered to the overmold material 105 after overmold deposition. Typically, the region of overmold material 105 is shaped such that it forms a recess into which the threaded connector 620 may be placed and affixed.

The region of overmold material 105 may also form an aperture 625 that aligns with the interior of the threaded connector 620 and the aperture through the PCB 610. Thus, a fastener may pass through all three of the threaded connector, the overmold material 105 and the PCB 110.

Although embodiments have been described herein with respect to certain structures, processes and methods, it should be appreciated that alternative embodiments may add or omit certain structures, operations and processes and still be within the spirit and scope of the disclosure. Accordingly, the proper scope of protection is set forth in the appended claims.

We claim:

1. A modularized printed circuit board, comprising:
a printed circuit board;
at least one electronic component affixed to the printed circuit board;
an overmold material adjacent at least a portion of the printed circuit board and defining a region of overmold material; and
a feature formed from the overmold material.

2. The modularized printed circuit board of claim 1, wherein the overmold material forms an environmental seal for the at least one electronic component.

3. The modularized printed circuit board of claim 1, wherein the feature extends laterally away from the printed circuit board and does not overlie the printed circuit board.

4. The modularized printed circuit board of claim 1, wherein the feature comprises a securing structure operative to secure the modularized printed circuit board to a support.

5. The modularized printed circuit board of claim 4, wherein the securing structure is affixed to the support.

6. The modularized printed circuit board of claim 5, wherein the securing structure is affixed directly to the support without the use of a fastener.

7. The modularized printed circuit board of claim 1, further comprising an internal stiffener at least partially surrounded by the feature, wherein the internal stiffener provides structural support for the feature.

8. The modularized printed circuit board of claim 1, further comprising a mounting structure at least partially received within the overmold material, the mounting structure formed from a material other than the overmold material and operative to couple the modularized printed circuit board to a support.

9. The modularized printed circuit board of claim 1, further comprising a second region of overmold material adjacent the first region of overmold material, wherein the first and second overmold materials are formed from different materials.

10. The modularized printed circuit board of claim 9, wherein the second region of overmold material is optically transparent.

11. The modularized printed circuit board of claim 10, wherein the second region of overmold material overlies an electronic component operative to receive light through the second region of overmold material.

12. The modularized printed circuit board of claim 1, further comprising:
a second material deposited adjacent at least a portion of the overmold material.

13. The modularized printed circuit board of claim 12, wherein the second material forms a conductive shield.

14. The modularized printed circuit board of claim 12, wherein the second material is softer than the overmold material and is operative to absorb kinetic energy.

15. The modularized printed circuit board of claim 14, wherein the second material is rougher than the overmold material and has a higher coefficient of friction than the overmold material.

16. The modularized printed circuit board of claim 1, wherein the feature is a connection feature forming an aperture operative to accept a connector therethrough.

17. The modularized printed circuit board of claim 1, wherein the aperture is a threaded aperture configured to receive a threaded fastener.

18. The modularized printed circuit board of claim 1, further comprising a connection structure adjacent the overmold material, the connection structure operative to accept a connector therethrough.

19. The modularized printed circuit board of claim 17, wherein the connection structure is at least partially encapsulated by the overmold material.
